(19) United States
(12) Patent Application Publication
(10) Pub. No.: US 2013/0280542 A1
(43) Pub. Date: Oct. 24, 2013

(54) METHOD FOR PRODUCING A PYROLYSIS COMPATIBLE COMPONENT FOR A COOKING APPLIANCE AND PYROLYSIS COMPATIBLE COMPONENT FOR A COOKING APPLIANCE

(71) Applicants: Jochen Herbolsheimer, Trostberg (DE); Frank Jördens, Traunstein (DE); Jürgen Salomon, Trostberg (DE); Philipp Schaller, Traunreut (DE); Gerhard Schmidmayer, Bad Endorf (DE)

(72) Inventors: Jochen Herbolsheimer, Trostberg (DE); Frank Jördens, Traunstein (DE); Jürgen Salomon, Trostberg (DE); Philipp Schaller, Traunreut (DE); Gerhard Schmidmayer, Bad Endorf (DE)

(73) Assignee: BSH BOSCH UND SIEMENS HAUSGERÄTE GMBH, Munich (DE)

(21) Appl. No.: 13/993,087

(22) PCT Filed: Dec. 16, 2011
(86) PCT No.: PCT/EP2011/073115

§ 371 Date: Jun. 11, 2013

(30) Foreign Application Priority Data
Dec. 22, 2010 (DE) 10 2010 063 887.0

(51) Int. Cl. C23C 16/50; F24C 15/16

(52) U.S. Cl. CPC C23C 16/50; F24C 15/16
USPC 428/448; 427/579; 427/575; 211/85.4; 423/335

(57) ABSTRACT

In a method for producing a pyrolysis compatible component of a cooking appliance, designed to carry out a pyrolysis operation a silicon dioxide coating is applied on a base part of the component by PECVD deposition. PECVD deposition can hereby involve high-rate PECVD deposition at a speed faster than 0.5 μm/min.

The invention relates to a method for producing a pyrolysis compatible component for a cooking appliance, the cooking appliance being configured to carry out a pyrolysis operation, in which method a base element of the component is provided and coated. The invention also relates to a pyrolysis compatible component for a cooking appliance.

With cooking appliances such as ovens it is known to provide support frames for holding food holders such as grill pans, baking sheets or grill shelves in the cooking compartment. Pull-out apparatuses such as telescopic rails for example can also be provided, on which such food holders can be positioned. In ovens which allow a pyrolysis operation, very high temperatures prevail during said pyrolysis operation, acting on the components in the cooking compartment. Conventional components, which can be left in the cooking compartment during the pyrolysis operation are coated with enamel but these are very complex to produce and therefore also expensive. Also they lose their typical stainless steel appearance over time. Enameled components are also easily damaged by impact so the enamel coating can be chipped.

The object of the present invention is to create a method for producing a pyrolysis compatible component for a cooking appliance and such a component, with which less wear results in respect of effect during a pyrolysis operation.

This object is achieved by a method having the features as claimed in claim 1 and a component having the features as claimed in claim 12.

With an inventive method for producing a pyrolysis compatible component for a cooking appliance, which is configured to carry out a pyrolysis operation, a base element of the component is provided and coated. A silicon dioxide coating is generated on the base part by PECVD (plasma-enhanced chemical vapor deposition) deposition. Such a specific type of application of such a specific material coating means that the pyrolysis compatibility of the component is significantly improved. The robustness and wear resistance of such components in respect of effects during pyrolysis can be substantially increased. In particular such an embodiment allows the staining and heat discoloration that occur with conventional components to be prevented during pyrolysis. The metallic character of the component is also maintained.

In particular it is possible for such a pyrolysis compatible component to be coated without using enamel, thereby preventing the occurrence of chipping.

Provision is preferably made for the silicon dioxide coating to be generated by high-rate PECVD deposition, in which the coating is generated at a speed faster than 0.5 μm/min, in particular around 1 μm/min. Such a procedure is particularly advantageous as the silicon dioxide coating can be applied in a particularly solid and stable manner.

This coating method is particularly resource-efficient compared with enameling, as high stoving temperatures are not required.

Provision is preferably made for the silicon dioxide coating to be generated with a thickness smaller than or equal to 10 μm, in particular between 50 nm and 2000 nm Such a thin silicon dioxide coating on the in particular metallic base part is sufficient to be able to achieve the abovementioned advantages and improvements perfectly. It also allows an extremely material-efficient coating method to be achieved.

Provision is preferably made for a microwave-induced plasma to be generated at 2.45 GHz during PECVD deposition. This allows protection against heat discoloration and chemical attack by food residues on the component to be particularly advantageously achieved.

The silicon dioxide coating is preferably generated in the vacuum using the abovementioned microwave-induced plasma. The plasma thus generated excites the so-called precursor (for example hexamethyldisiloxane) so that a highly adhesive, pore-free coating, which is very dense compared with those produced using normal plasma procedures, is generated on the component.

Provision is preferably made for impurity atoms to be introduced into a coating structure encompassing the silicon dioxide coating. By varying the process parameters during deposition it is possible to incorporate these impurity atoms in the coating composite so that gradient coatings are generated. This for example allows compensation for different thermal expansion coefficients between the base part and the coating or variation of the surface energy of the coating.

Provision is preferably made for carbon and/or hydrogen to be introduced as the impurity atoms. This allows the abovementioned properties to be achieved in a particularly precise and permanent manner.

Provision is preferably made for the coating structure to be configured with a first coating which comprises silicon, oxygen, carbon and hydrogen, and for it to be configured as the coating next to the base part. This first coating is preferably a SiOₓC_{y}H_{z} coating (where 0≦x,y,z≦2).

Provision is preferably made for the coating structure to be configured with a second coating which comprises silicon and carbon and is configured on the first coating, the concentration of carbon in the second coating being lower than in the first coating. A concentration gradient is therefore established in respect of the two coatings, with regard in particular to the carbon atoms and oxygen atoms. This can improve the abovementioned advantages with regard to the equalization of the thermal expansion coefficients or the variation of the surface energy.

It is also possible for the coating structure to be configured with a second coating which comprises silicon, oxygen, carbon and hydrogen and is configured on the first coating, the concentration of oxygen, carbon and hydrogen in the second coating being different from in the first coating. A concentration gradient is therefore established in respect of the two coatings, with regard in particular to the hydrogen atoms, carbon atoms and oxygen atoms. This can improve the abovementioned advantages with regard to the equalization of the thermal expansion coefficients or the variation of the surface energy.

Provision is preferably made for the silicon dioxide coating to be configured in the manner of a third coating on the second coating.

Such a coating structure is particularly expedient in respect of the abovementioned advantages and improvements.

Provision can be made for each of the three coatings of the coating structure to be configured with the same coating thickness. However provision can also be made for the three coatings to be generated with different coating thicknesses.

The base part is preferably configured from metal.

The invention also relates to a pyrolysis compatible component for a cooking appliance, having a base part that is coated. A silicon dioxide coating is configured as the coating, being applied by PECVD deposition, in particular by high-rate PECVD deposition, to the base part.

The component is preferably a grill shelf or food holder or a telescopic pull-out apparatus for holding a food holder. The food holder provided can be for example a grill shelf, baking sheet or grill pan. The support frame for holding a food holder can be configured for example from bars as a grill frame and can be inserted into and removed again from the cooking compartment reversibly in a non-destructive manner.

Provision is preferably made for a coating composite to be configured on the base part, comprising a first coating containing silicon, carbon, oxygen and hydrogen, on which a second coating containing silicon and carbon is configured, the concentration of carbon in the second coating being lower than in the first coating, and the silicon dioxide coating being configured outward on the second coating.

Provision is preferably made for a coating composite to be configured on the base part, comprising a first coating containing silicon, carbon, oxygen and hydrogen, on which a second coating containing silicon, oxygen, carbon and hydrogen is—optionally—configured, the concentration of oxygen, carbon and hydrogen in the second coating being different from in the first coating, and the silicon dioxide coating being configured outward on the second coating.

Exemplary embodiments of the invention are described in more detail below with reference to schematic drawings, in which:

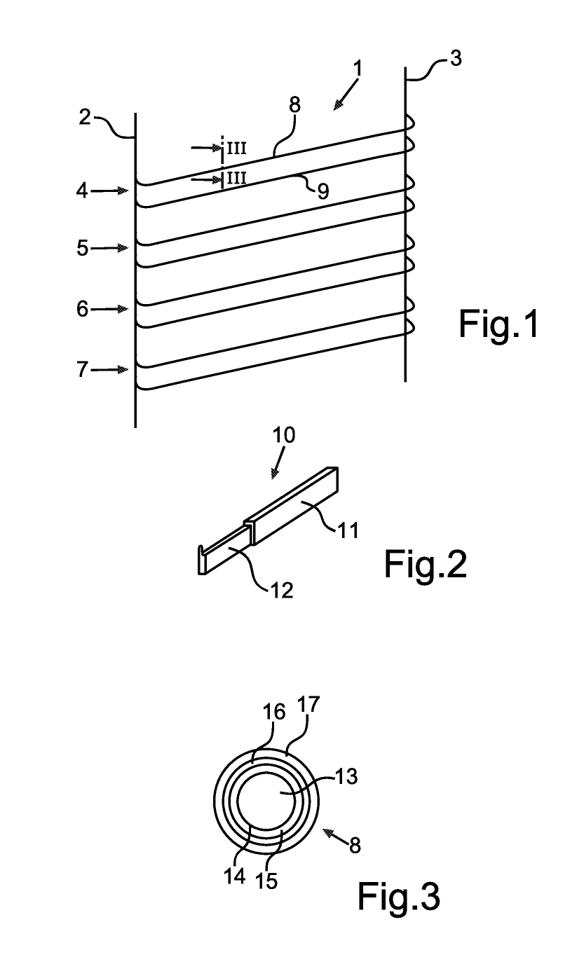

FIG. 1 shows a simplified diagram of a support frame for holding a food holder;

FIG. 2 shows a telescopic pull-out apparatus for holding a food holder; and

FIG. 3 shows a sectional diagram through a bar of the support frame according to FIG. 1.

Identical elements or those of identical function are shown with identical reference characters in the figures.

FIG. 1 shows a support frame 1 made up of bars. The support frame 1 can be introduced into the cooking compartment and be disposed for example on a vertical side wall of a muffle. The support frame 1 comprises two vertical retaining bars 2 and 3, on which a plurality of guide bars are disposed. These are assigned to one another in pairs, respectively forming an insertion guide. In the exemplary embodiment provision is made for four insertion guides 4, 5, 6 and 7 to be predefined, being at different height levels when viewed in the vertical direction. Insertion levels for a food holder in the muffle are also thus predefined. For example the insertion guide 4 comprises two guide bars 8 and 9 aligned parallel to one another, between which a part of the food holder can be inserted and held. The support frame 1 is produced as a pyrolysis compatible component, which comprises a base part made of metal, to the outside of which a coating composite is applied. This is generated by high-rate PECVD deposition.

FIG. 2 shows a simplified perspective view of a telescopic pull-out apparatus 10, which is also configured to hold a food holder and can be fastened to a vertical side wall of a muffle in a cooking compartment. The telescopic pull-out apparatus 10 in the exemplary embodiment comprises two rails 11 and 12, the rail 11 being the positionally fixed rail and the rail 12 being the pull-out rail that can be moved relative thereto. This telescopic pull-out apparatus 10 is also a pyrolysis compatible component, which is configured respectively from a base part, the outside of which is coated with a coating composite which was generated by high-rate PECVD deposition. The coating composite can comprise up to three coatings on both components, with a SiOₓC_{y}H_{z} coating first being configured on the base part as the first coating and a SiOₖCₗHₘ coating then being configured thereon as the second coating (where 0≦x,y,z,k,l,m≦2 and x≠k; y≠l; z≠m). A silicon dioxide coating is then configured outward on this second coating.

A sectional diagram through the bar 8 is shown in FIG. 3. It shows the base part 13. Configured on its outside 14 is the first coating 15, which, as mentioned above, is a SiOₓC_{y}H_{z} coating. The second coating 16, which is a SiOₖCₗHₘ coating, is then applied to this. The silicon dioxide coating 17 is then configured on the outside. The three coatings 15 to 17 have a concentration gradient in respect of the impurity atoms carbon and hydrogen, decreasing from the inside outward.

The coatings 15 to 17 are also applied using a high-rate PECVD deposition procedure, the coatings being generated at a speed of up to around 6 μm/min (preferably 0.5-1μm/min) A microwave-induced plasma is generated at 2.45 GHz in the process. The silicon dioxide coating 17 is generated in the vacuum using said microwave-induced plasma.

### List of Reference Characters

1 Support frame

2, 3 Retaining bars

4, 5, 6, 7 Insertion guides

8, 9 Guide bars

10 Telescopic pull-out apparatus

11, 12 Rails

13 Base part

14 Outside

15, 16, 17 Coatings

1-14. (canceled)

15. A method for producing a pyrolysis compatible component for a cooking appliance, the cooking appliance being configured to carry out a pyrolysis operation, said method comprising applying a silicon dioxide coating on a base part of the component by PECVD deposition.

16. The method of claim 15, wherein the silicon dioxide coating is applied by high-rate PECVD deposition at a speed faster than 0.5 μm/min.

17. The method of claim 15, wherein the silicon dioxide coating is applied by high-rate PECVD deposition at a speed of around 1 μm/min.

18. The method of claim 15, wherein the silicon dioxide coating is applied with a thickness smaller than or equal to 10 μm.

19. The method of claim 15, wherein the silicon dioxide coating is applied with a thickness between 50 nm and 2000 nm.

20. The method of claim 15, wherein a microwave-induced plasma is generated at 2.45 GHz during PECVD deposition.

21. The method of claim 15, further comprising introducing impurity atoms into a coating structure encompassing the silicon dioxide coating on the base part.

22. The method of claim 21, wherein the impurity atoms include at least one of carbon and hydrogen.

23. The method of claim 21, wherein the impurity atoms are introduced with a defined concentration gradient in a direction of a coating thickness of the silicon dioxide coating.

24. The method of claim 23, wherein the coating structure includes a first coating, which comprises silicon, oxygen, carbon and hydrogen and is configured as a coating next to the base part.

25. The method of claim 24, wherein the coating structure includes a second coating, which comprises silicon, oxygen, carbon and hydrogen and is formed on the first coating, wherein a concentration of oxygen, carbon and hydrogen in the second coating is different from a concentration of oxygen, carbon and hydrogen in the first coating.

26. The method of claim 25, wherein the silicon dioxide coating is applied on the first coating or second coating.

27. The method of claim 15, wherein the base part is configured from metal.

28. A pyrolysis compatible component for a cooking appliance, said component comprising:
a base part; and
a silicon dioxide coating applied by PECVD deposition on the base part.

29. The component of claim 28, wherein PECVD deposition includes high-rate PECVD deposition.

30. The component of claim 28, configured as a support frame for holding a food holder or a food holder or a telescopic pull-out apparatus for holding a food holder.

31. The component of claim 28, further comprising a coating composite formed on the base part and comprising a first coating containing silicon, carbon, oxygen and hydrogen, and a second coating containing silicon, oxygen, carbon and hydrogen, with the silicon dioxide coating being formed on the first coating or second coating, wherein a concentration of oxygen, carbon and hydrogen in the second coating is lower than a concentration of oxygen, carbon and hydrogen in the first coating.
